(19) United States
(12) Patent Application Publication
(10) Pub. No.: US 2014/0077316 A1
(43) Pub. Date: Mar. 20, 2014

(54) WAFER BONDING AND RELATED METHODS AND APPARATUS

(71) Applicant: Sand 9, Inc., Cambridge, MA (US)

(72) Inventors: Andrew Sparks, Cambridge, MA (US); Jan H. Kuypers, Cambridge, MA (US)

(73) Assignee: Sand 9, Inc., Cambridge, MA (US)

(21) Appl. No.: 13/859,363

(22) Filed: Apr. 9, 2013

Related U.S. Application Data
(60) Provisional application No. 61/622,272, filed on Apr. 10, 2012.

(51) Int. Cl. B81C 1/00; B81C 3/00; B81B 3/00

(52) U.S. Cl. CPC B81C 1/00134; B81B 3/0018; B81C 3/001
USPC 257/415; 438/51

(57) ABSTRACT

Techniques for bonding wafers together are described. The wafers may be bonded via a eutectic bond. In some instances, one wafer has an integrated circuit and a second wafer has a microelectromechanical systems (MEMS) feature. The wafer with an integrated circuit may have a metal formed thereon for bonding purposes and the wafer with the MEMS feature may have a semiconductor formed thereon for bonding purposes.

### CROSS-REFERENCE TO RELATED APPLICATIONS

This Application claims the benefit under 35 U.S.C. §119(e) of U.S. Provisional Application Ser. No. 61/622,272, entitled “WAFER BONDING AND RELATED METHODS AND APPARATUS” filed on Apr. 10, 2012 under Attorney Docket No. G0766.70040US00, which is hereby incorporated herein by reference in its entirety.

### BACKGROUND

1. Field

The present application relates to bonding of wafers and related methods and apparatus.

2. Related Art

Microelectromechanical systems (MEMS) are small mechanical structures with integrated electromechanical transducers to induce and/or detect their mechanical motion. Examples of MEMS devices include oscillators, accelerometers, gyroscopes, microphones, pressure sensors, switches, and filters.

Typically, an integrated circuit (IC) is packaged with a MEMS device. The IC controls operation of the MEMS device, and can perform functions such as signal amplification, modulation and demodulation, conversion between analog and digital signal domains, and programmability for compensation of manufacturing or operating variations.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 is a flowchart of a process for bonding a MEMS wafer to an IC wafer, according to a non-limiting embodiment.

FIGS. 2A-2H illustrate a process flow of a non-limiting example of fabrication steps consistent with the process of FIG. 1, according to a non-limiting embodiment.

### SUMMARY

According to an aspect of the present application, a method is provided, comprising forming a microelectromechanical (MEMS) device on a first wafer, forming a patterned germanium layer on the first wafer, forming an integrated circuit on a second wafer, and exposing at least part of a metallization layer on the second wafer. The method further comprises depositing gold on the at least part of the metallization layer, aligning the patterned germanium layer with the gold, and forming a eutectic bond between the patterned germanium layer and the gold to bond the first wafer to the second wafer.

According to an aspect of the present application, a method is provided comprising forming a gold eutectic bond between a microelectromechanical (MEMS) wafer and an integrated circuit (IC) wafer.

According to an aspect of the present application, a capped microelectromechanical (MEMS) device is provided, comprising a MEMS wafer comprising a MEMS device and a patterned germanium layer, and an integrated circuit (IC) wafer comprising an IC and a patterned metallization layer, the IC wafer further comprising a gold layer formed on at least part of the patterned metallization layer. The MEMS wafer and IC wafers are bonded together in a configuration in which the patterned germanium layer and the gold layer form a eutectic bond.

### DETAILED DESCRIPTION

Although some MEMS and IC components may be fabricated using silicon-based technologies, integrating the two on a single wafer is prohibitively costly. Moreover, incompatibility in manufacturing processes complicates their integration. For instance, certain materials which may be used in fabricating MEMS devices are generally not allowed in facilities used to fabricate ICs because the materials may contaminate the equipment used to fabricate the ICs, thus posing a significant risk to the quality of the fabrication facility and resulting products. Gold, for instance, is one such material. Gold is conventionally not allowed in facilities which fabricate silicon ICs. If gold is introduced into a silicon IC, for instance as a contaminant, it may produce undesirable results. For instance, gold can alter the physical behavior of silicon based devices, such as silicon transistors, thus significantly harming or destroying them. Thus, ICs and MEMS devices are typically formed on separate wafers in separate manufacturing environments.

According to an aspect of the present technology, a method of bonding a MEMS wafer including a MEMS device to an IC wafer including an IC to be connected to the MEMS device includes forming a gold eutectic bond between the MEMS and IC wafers. Contrary to conventional practice, gold may be put on the IC wafer as a bonding material. Germanium, silicon, or other semiconductor may be placed on the MEMS wafer. The two wafers may then be bonded by eutectic bonding to form a gold/germanium (AuGe) bond. The bond may facilitate the transfer of electric signals from the IC wafer to the MEMS device and vice versa.

In accordance with a non-limiting embodiment, a MEMS device and an IC are fabricated separately on individual silicon wafers. Packaging may then involve wafer-level chip-scale packaging (WLCSP), where the two wafers are brought into physical contact and their faces are chemically bonded together. To facilitate electrical contact between the two wafers, the bond interface is, and in some embodiments must be, formed from a metal and/or doped semiconductor.

According to an aspect of the technology, wafer bonding with a conductive interface may be achieved through eutectic bonding. Fusion bonding, e.g., silicon-to-silicon bonding, typically requires high temperature processing which would degrade both MEMS and IC performance. Thermocompression bonding, e.g., gold-to-gold, requires high forces such that wafer-scale bond integrity can be challenging. Eutectic bonding is an attractive alternative, where component “A” is deposited on the MEMS wafer and component “B” is deposited on the IC wafer. If components A and B form a eutectic binary alloy system, the eutectic temperature will be lower than the melting point of either pure component. Bonding near this relatively low eutectic temperature will result in alloying of the components, thus resulting in a hermetic seal between the wafers and a strong bond. By the appropriate selection of components A and B, a low eutectic temperature can be achieved while maintaining high strength and sufficient electrical conductivity.

According to a non-limiting embodiment, a gold-germanium bond is formed. Gold-germanium may have a eutectic temperature of 361° C. (or approximately 361° C.). Contrary to convention, the gold may be disposed on the IC wafer. The germanium may be disposed and patterned on the MEMS wafer. The wafers may then be bonded together.

According to an alternative non-limiting embodiment, a gold-silicon bonding system is used, having a eutectic temperature of 361° C. (or approximately 361° C.). Contrary to convention, the gold may be disposed on the IC wafer. The silicon may be disposed and patterned on the MEMS wafer. The wafers may then be bonded together.

The aspects described above, as well as additional aspects, will now be described in greater detail. These aspects may be used individually, all together, or in any combination of two or more.

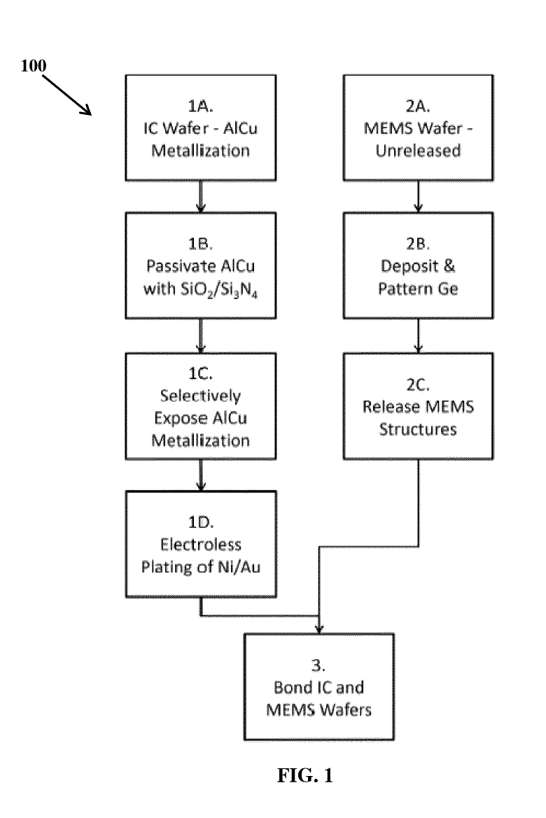

A process for bonding a MEMS wafer and an IC wafer together according to a non-limiting embodiment of the present technology is illustrated in FIG. 1 as method 100. Steps 1A-1D illustrate processing of an IC wafer only, while steps 2A-2C apply only to the MEMS wafer, in this non-limiting embodiment.

Processing of the IC wafer is described first, relating to steps 1A-1D. As shown in step 1A, the IC wafer has its final metallization layer patterned using AlCu. Alternatively, other metals common to complementary metal oxide semiconductor (CMOS) processing may be used, such as Al, AlSi, AlSiCu, Cu, etc. It should be appreciated that various steps for forming the IC on the IC wafer may precede step 1A, but that for simplicity the illustrated process begins at step 1A.

In step 1B, the entire IC wafer surface is passivated with silicon oxide (SiO2), silicon nitride (Si3N4), and/or some other dielectric film, though not all embodiments require that the entire surface be passivated (e.g., in some non-limiting embodiments a portion of the surface may be passivated).

The passivation is then selectively removed in step 1C to selectively expose the underlying AlCu metallization, thus defining what will be the bond lines and wafer-to-wafer interconnects. The pattern of the exposed AlCu may take any suitable shape and configuration, as the various aspects described herein are not limited in this respect. For example, the exposed AlCu may form a ring, discrete contact points, or any other suitable configuration.

As mentioned previously, according to an aspect of the present application a gold eutectic bond is formed, with the gold having been formed on the IC wafer. Thus, in the non-limiting example of FIG. 1, deposition of Au is performed in step 1D. The Au deposition may be performed by electroless plating in a non-limiting embodiment, although alternative deposition processes may be used.

In anticipation of Au deposition on the IC wafer in 1D, a diffusion barrier layer such as Ni, TiW, TiN, Ta or other metal may, and in some embodiments must, be deposited on the exposed AlCu metallization. The diffusion barrier may prevent the subsequently deposited Au from diffusing into the underlying metallization (e.g., Al or Cu metallization, as a non-limiting example) or other layers, which may degrade performance. The Au is then deposited through electroless plating. The IC wafer is then ready for bonding.

According to an aspect of the technology, various steps illustrated in FIG. 1 may be performed in different manufacturing environments (e.g., different buildings, rooms, etc.). For example, because gold is conventionally not allowed in integrated circuit fabrication facilities, step 1D may be performed outside of an IC fabrication facility. In some such embodiments, steps 1A-1C may be performed in an IC fabrication facility, and the IC wafer may then be removed from the IC fabrication facility for purposes of performing step 1D. According to another embodiment, steps 1A-1B may be performed in an IC fabrication facility and the IC wafer may then be removed from the IC fabrication facility for purposes of performing steps 1C-1D. Additional alternatives are possible in terms of which steps are performed in different manufacturing environments, if any.

In some embodiments, steps 2A-2C may be performed in a MEMS fabrication facility, which may be distinct from the IC fabrication facility used in processing the IC wafer.

As used herein, different manufacturing environments refers to different environments with respect to contamination (e.g., contamination free manufacturing). Different manufacturing environments may be provided in various manners. For example, different manufacturing environments may be provided by separate rooms within the same facility, by different buildings within the same facility, or by distinct facilities. Thus, it should be appreciated that those aspects in which various processing steps are performed in different manufacturing environments are not limited to the manner in which the different environments are provided, unless otherwise stated.

Turning now to the MEMS wafer, in step 2A, the MEMS wafer may be substantially formed. For example, if the MEMS device to be formed is a MEMS resonator, the resonator may be substantially completed by step 2A. However, in this non-limiting embodiment, any mechanical structures of the MEMS device are not yet released (freed to move) at step 2A. For example, if the MEMS device to be formed is a resonator, the resonating body may not yet be released by step 2A.

In step 2B, Ge may be deposited using evaporation, sputtering, or chemical vapor deposition (CVD) and is then patterned on the wafer. Si or SiGe can be substituted for Ge in this step, depending on the maximum allowable deposition temperature. If the bond interface between the IC and MEMS wafers is to be used as an electrical conductive path between the wafers, the Ge layer on the MEMS wafer can be deposited onto conductive routing traces on the MEMS wafer. However, not all embodiments are limited in this respect. Suitable materials for any such traces comprise AlCu, TiW, Au, Al, AlSi, Mo, Cu, Ni, TiN, and Ta, amongst others. These metals may diffuse into the final eutectic bond, but are not critical to the formation of the bond.

The MEMS devices may be released in step 2C using methods such as wet or vapor HF etch, XeF2 etch, or other suitable techniques.

In step 3 of method 100, the MEMS and IC wafers are brought together, optionally aligned (in any suitable manner), and bonded by increasing the temperature to at least the eutectic temperature. For example, assuming a gold-germanium eutectic bond is to be formed, the temperature may be increased beyond 360° C. for a sustained period of time suitable to form a eutectic bond (e.g., between 10-20 minutes in some non-limiting embodiments, between 5-30 minutes in some non-limiting embodiments, greater than 10 minutes in some non-limiting embodiments, greater than 5 minutes in some non-limiting embodiments, or any other suitable duration). Thus, a eutectic bond may result between the gold on the IC wafer and the Ge on the MEMS wafer, bonding the wafers themselves together.

For those steps of the process illustrated in FIG. 1 in which a metal is deposited, it should be appreciated that the metals can be deposited in any of various ways, including evaporation, sputtering, and electroplating. A preferred embodiment utilizes electroless plating to simplify the fabrication process, though alternative deposition techniques are possible.

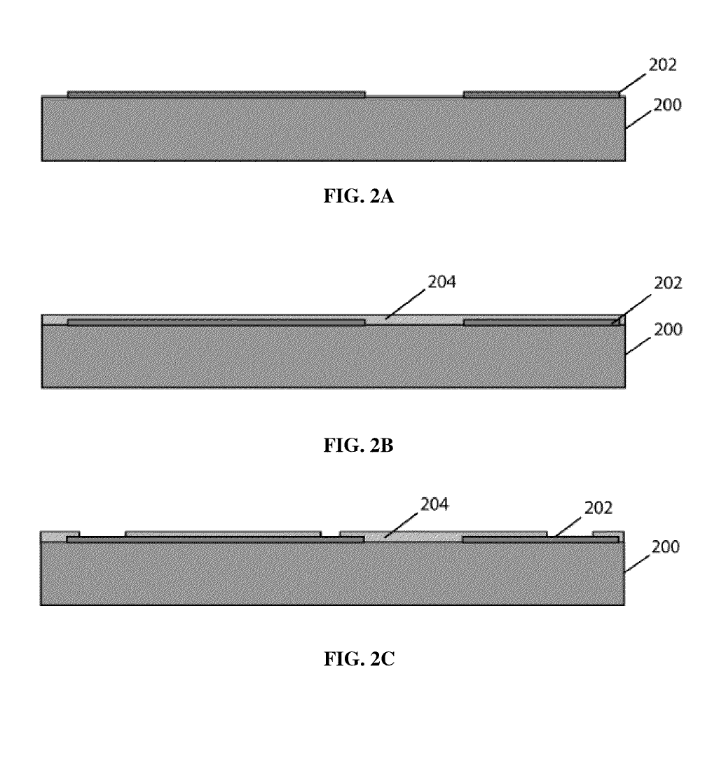

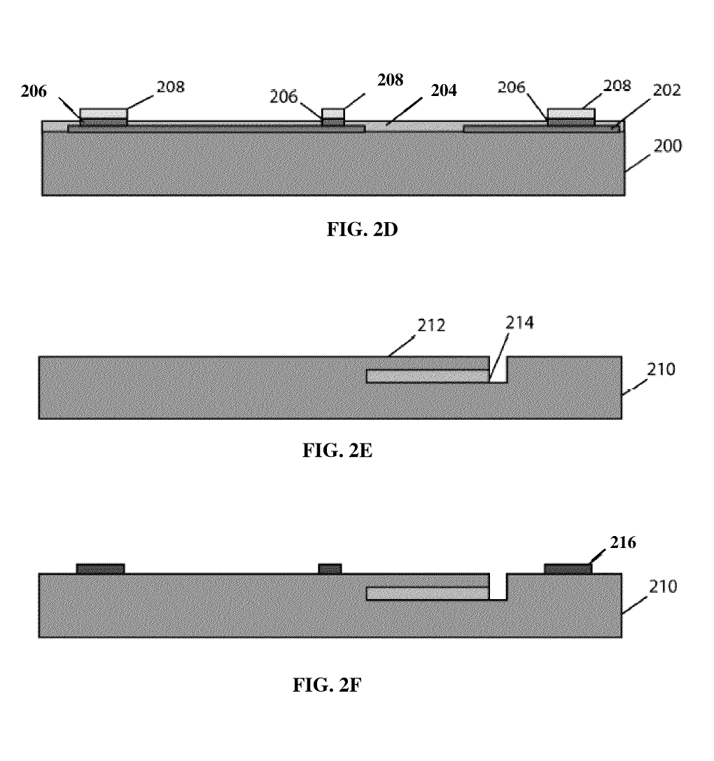

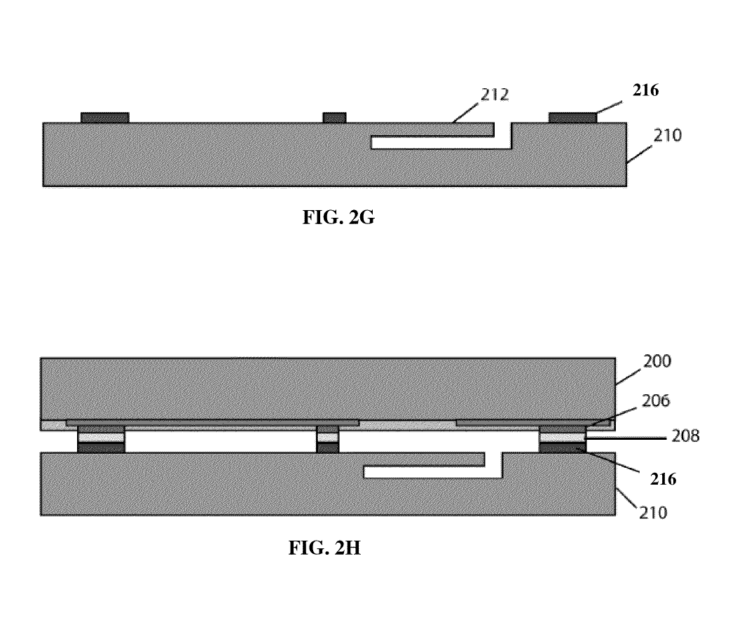

As previously described, FIGS. 2A-2H provide a non-limiting illustration of a process sequence (in cross-sectional views) consistent with the process of FIG. 1, illustrating the progress of the structure for each of the steps of FIG. 1. That is, the structure of FIG. 2A corresponds to the result of step 1A of method 100, the structure of FIG. 2B corresponds to the result of step 1B, the structure of FIG. 2C corresponds to the result of step 1C of method 100, the structure of FIG. 2D corresponds to the result of step 1D of method 100, the structure of FIG. 2E corresponds to the result of step 2A of method 100, the structure of FIG. 2F corresponds to the result of step 2B of method 100, the structure of FIG. 2G corresponds to the result of step 2C of method 100, and the structure of FIG. 2H corresponds to the result of step 3 of method 100. It should be appreciated that the structures illustrated in FIGS. 2A-2H, in terms of shape, configuration, placement, etc. are non-limiting.

Again, steps 1A-1C refer to processing of an IC wafer. As shown in FIG. 2A, a substrate 200 may have a metallization 202 formed thereon. The metallization may be formed in any suitable manner and may be patterned (or not, as the case may be) to have any suitable shape. Thus, the shape illustrated in FIG. 2A is non-limiting. It should be noted that the structure illustrated in FIG. 2A may represent part of a wafer or an entire wafer, i.e., an IC wafer may include one or more copies of the structures illustrated in FIG. 2A.

As shown in FIG. 2B, in step 1B of method 100 a passivation layer 204 may be formed over the metallization 202 and exposed substrate 200 in any suitable manner, for example by deposition. The passivation may be formed of any suitable material, such as those previously described in connection with step 1B, and may have any suitable thickness.

As shown in FIG. 2C, in step 1C the metallization 202 may be selectively exposed by selective etching of the passivation 204, or in any other suitable manner.

As shown in FIG. 2D, in step 1D a diffusion barrier layer 206 and gold layer 208 may be formed on the exposed portions of the metallization 202, in any suitable manner. The diffusion barrier layer 206 may be any suitable material, such as those previously described with respect to step 1D. The gold layer 208 may be formed by electroless plating, or in any other suitable manner.

Turning now to the MEMS wafer, as mentioned previously, step 2A may begin with a MEMS wafer having a MEMS device formed thereon. Referring to FIG. 2E, the MEMS substrate 210 may include a MEMS device 212 and a cavity layer 214. Thus, the MEMS device 212 is not yet released in this step. The MEMS device 212 may be any MEMS device, as the various aspects described herein are not limited to use with any particular MEMS devices. For example, the MEMS device 212 may be part of a mechanical resonator. As with the previously described IC wafer, it should be appreciated that the structure illustrated in FIGS. 2E-2G may represent part of a MEMS wafer or an entire MEMS wafer, i.e., a MEMS wafer may include one or more copies of the structures illustrated in FIGS. 2E-2G.

As shown in FIG. 2F, in step 2B a layer of germanium 216 may be deposited and patterned on the MEMS substrate 210. The layer of germanium 216 may be patterned to have any suitable configuration. As can be seen in FIG. 2F, in one non-limiting embodiment the germanium layer is patterned to substantially align with the gold layer on the IC wafer shown in FIG. 2D.

As shown in FIG. 2G, in step 2C the MEMS device 212 may be released by removing the cavity layer 214, for instance by etching or in any other suitable manner.

As shown in FIG. 2H, the IC substrate 200 and MEMS substrate 210 may then be bonded in step 3. The wafers including such substrates may be aligned such that the gold layer 208 of the IC substrate aligns with the patterned germanium layer 216 of the MEMS substrate, and then the wafers may be brought together and heated to a temperature above the eutectic point of gold-germanium (e.g., above 360° C., resulting in a eutectic bond between the wafers. Thus, the resulting structure illustrated in FIG. 2H may provide a strong bond which conducts electrical signals between the wafers.

Optionally, additional post-processing steps may be performed. For example, after bonding, the wafers may then be diced and packaged, though not all embodiments are limited in this respect.

Variations on the process of FIGS. 1 and 2A-2H are possible. For example, rather than using a germanium layer 216 in FIG. 2H, a silicon layer may be used. Other semiconductor materials suitable for forming a eutectic bond with gold may alternatively be used. Moreover, while FIGS. 1 and 2A-2H illustrate a scenario in which gold is formed on the IC wafer and germanium on the MEMS wafer, the reverse arrangement is also possible, i.e., in an alternative non-limiting embodiment the gold may be formed on the MEMS wafer the germanium on the IC wafer.

While the IC wafer has been described as including an IC circuit, it should be appreciated that not all embodiments are limited in this respect. For example, the IC wafer may be a dummy cap wafer in some embodiments, lacking IC circuitry. In some such embodiments, the IC wafer may include through silicon vias (TSVs) or other structures enabling electrical access to the MEMS wafer from outside the capped device, though not all embodiments are limited in this respect. Thus, it should be appreciated that according to an embodiment of the present application, a capped MEMS device may be formed from a MEMS wafer including a MEMS device and a dummy cap lacking integrated circuitry. The capped MEMS device may be connected to external circuitry in any suitable manner.

Furthermore, while FIG. 1 illustrates that release of the MEMS device occurs after deposition and patterning of germanium, not all embodiments are limited in this respect. For example, the various aspects described herein are not limited to application with MEMS devices which require release. Some MEMS devices may not require release, and therefore the release step may be omitted. Alternatively, in some embodiments, release of a MEMS device may occur prior to deposition and patterning of germanium (or other material). Thus, the various aspects are not limited in this respect.

It should be understood that the various embodiments shown in the Figures are illustrative representations, and are not necessarily drawn to scale. Reference throughout the specification to “one embodiment” or “an embodiment” or “some embodiments” means that a particular feature, structure, material, or characteristic described in connection with the embodiment(s) is included in at least one embodiment, but not necessarily in all embodiments. Consequently, appearances of the phrases “in one embodiment,” “in an embodiment,” or “in some embodiments” in various places throughout the Specification are not necessarily referring to the same embodiment.

Unless the context clearly requires otherwise, throughout the disclosure, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list; all of the items in the list; and any combination of the items in the list.

Having thus described several embodiments, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

1. A method, comprising:
forming a microelectromechanical (MEMS) device on a first wafer;
forming a patterned germanium layer on the first wafer;
forming an integrated circuit on a second wafer;
exposing at least part of a metallization layer on the second wafer;
depositing gold on the at least part of the metallization layer;
aligning the patterned germanium layer with the gold; and
forming a eutectic bond between the patterned germanium layer and the gold to bond the first wafer to the second wafer.

2. The method of claim 1, wherein forming the integrated circuit on the second wafer is performed in a first fabrication environment and wherein depositing gold on the at least part of the metallization layer is performed in a second fabrication environment.

3. The method of claim 1, further comprising forming a diffusion barrier layer on the second wafer configured to prevent diffusion of the gold into the integrated circuit.

4. The method of claim 1, wherein the second wafer comprises a silicon substrate on which the integrated circuit is formed.

5. The method of claim 1, further comprising forming a diffusion barrier layer on the at least part of the metallization layer, and wherein depositing gold on the at least part of the metallization layer comprises depositing gold on the diffusion barrier layer.

6. The method of claim 5, wherein the diffusion barrier layer comprises a metal.

7. The method of claim 1, wherein the metallization layer comprises a metal selected from the group consisting of: AlCu, Al, AlSi, AlSiCu, and Cu.

8. The method of claim 1, wherein the MEMS device comprising a mechanical resonating structure, and wherein the method further comprises releasing the mechanical resonating structure after forming the patterned germanium layer on the first wafer and prior to forming the eutectic bond.

9. The method of claim 1, further comprising dicing the first and second wafers after forming the eutectic bond.

10. A method comprising:
forming a gold eutectic bond between a microelectromechanical (MEMS) wafer and an integrated circuit (IC) wafer.

11. The method of claim 10 wherein forming the gold eutectic bond comprises forming a eutectic bond between gold and germanium.

12. The method of claim 11, wherein the gold is deposited on the IC wafer and wherein the germanium is deposited on the MEMS wafer.

13. The method of claim 10, wherein forming the gold eutectic bond comprises forming a eutectic bond between gold and silicon.

14. The method of claim 13, wherein the gold is deposited on the IC wafer and wherein the silicon is deposited on the MEMS wafer.

15. The method of claim 11, wherein the gold is deposited on the MEMS wafer and wherein the germanium is deposited on the IC wafer.

16. The method of claim 10, further comprising forming a MEMS resonator on the MEMS wafer prior to forming the gold eutectic bond.

17. A capped microelectromechanical (MEMS) device, comprising:
a MEMS wafer comprising a MEMS device and a patterned germanium layer;
an integrated circuit (IC) wafer comprising an IC and a patterned metallization layer, the IC wafer further comprising a gold layer formed on at least part of the patterned metallization layer,
wherein the MEMS wafer and IC wafers are bonded together in a configuration in which the patterned germanium layer and the gold layer form a eutectic bond.

18. The capped MEMS device of claim 17, wherein the IC wafer further comprises a diffusion barrier layer formed between the patterned metallization layer and the gold layer.

19. The capped MEMS device of claim 17, wherein the MEMS device comprises a MEMS resonator.
